(19) United States
(12) Patent Application Publication
(10) Pub. No.: US 2008/0041303 A1
(43) Pub. Date: Feb. 21, 2008

(54) Systems for Masking a Portion of an Envelope Near its Perimeter

(75) Inventors: Fred Casto, Omaha, NE (US); Jon Gates, Honey Creek, IA (US); Ray Stuck, Omaha, NE (US); Corey Tunink, LaVista, NE (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: First Data Corporation, Greenwood Village, CO (US)

(21) Appl. No.: 11/751,530

(22) Filed: May 21, 2007

Related U.S. Application Data
(60) Provisional application No. 60/822,568, filed on Aug. 16, 2006.

(51) Int. Cl. C23C 14/04

(52) U.S. Cl. 118/76; 427/285

(57) ABSTRACT

According to the invention, a system for masking a portion of an envelope near the envelope's perimeter is disclosed. The system may include a supply mechanism configured to support an envelope, and provide the envelope to a first position. The system may also include a transport mechanism configured to move the envelope from the first position to a second position. The system may further include a masking apparatus configured to adhere a masking element to a portion of the envelope near the envelope's perimeter.

### PRIORITY CLAIM

This application claims priority to Provisional U.S. Patent Application No. 60/822,568 filed Aug. 16, 2006, entitled “SYSTEMS FOR MASKING A PORTION OF AN ENVELOPE NEAR ITS PERIMETER,” the entire disclosure of which is hereby incorporated by reference as if fully set forth herein.

### BACKGROUND OF THE INVENTION

This invention relates generally to mail processing systems. More specifically the invention relates to methods of applying masking elements to the exterior of an envelope.

In some mail processing systems, various bar codes and other markings may be produced on the exterior of an envelope to assist in either pre-mailing processing or transportation of the mail by a carrier. In bulk arrangements, the total volume of mailing may be high, requiring high speed processing by various marking machines. While the number of errors per batch of envelopes may be relatively low, high processing speeds may result in a great number of mis-marked envelopes being created. If these errors cannot be fixed quickly, then overall production may be slowed. The systems and methods of the present invention solve these and other problems.

### BRIEF DESCRIPTION OF THE INVENTION

In one embodiment, a system for masking a portion of an envelope near the envelope's perimeter is provided. The system may include a supply mechanism configured to support an envelope, and provide the envelope to a first position. The system may also include a transport mechanism configured to move the envelope from the first position to a second position. The system may further include a masking apparatus configured to adhere a masking element to a portion of the envelope near the envelope's perimeter.

In another embodiment, a system for masking a portion of an envelope near the envelope's perimeter is provided. The system may include a means for providing an envelope to a first position. The system may also include a means for moving the envelope from the first position to a second position. The system may further include a means for adhering a masking element to a portion of the envelope near the envelope's perimeter.

In another embodiment, a method for masking a portion of an envelope near the envelope's perimeter is provided. The method may include providing an envelope and moving the envelope between a first position and a second position. The method may further include adhering a masking element to a portion of the envelope near the envelope's perimeter.

### BRIEF DESCRIPTION OF THE DRAWINGS

The present invention is described in conjunction with the appended figures:

FIG. 1 is an axonometric drawing of a system for masking a portion of an envelope near the envelope's perimeter;

FIG. 2 is a perspective view of the transport mechanism and masking apparatus of the system shown in FIG. 1;

FIG. 3 is a perspective view of the input and output areas of the system shown in FIG. 1;

FIG. 4 is a perspective view of a portion of the masking apparatus showing a masking element being applied to an envelope;

FIG. 5 is a block diagram of one method of the invention for masking a portion of an envelope near the envelope's perimeter; and

FIG. 6 is a block diagram of an exemplary computer system capable of being used in at least some portion of the systems of the present invention, or capable of controlling at least some portion of the systems of the present invention.

In the appended figures, similar components and/or features may have the same numerical reference label. Further, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION OF THE INVENTION

The ensuing description provides exemplary embodiments only, and is not intended to limit the scope, applicability or configuration of the disclosure. Rather, the ensuing description of the exemplary embodiments will provide those skilled in the art with an enabling description for implementing an exemplary embodiment. It being understood that various changes may be made in the function and arrangement of elements without departing from the spirit and scope of the invention as set forth in the appended claims.

Specific details are given in the following description to provide a thorough understanding of the embodiments. However, it will be understood by one of ordinary skill in the art that the embodiments may be practiced without these specific details. For example, circuits, systems, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Also, it is noted that individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination corresponds to a return of the function to the calling function or the main function.

Furthermore, embodiments may be implemented and/or controlled by hardware, software, firmware, middleware, microcode, hardware description languages, or any combination thereof. When implemented and/or controlled by software, firmware, middleware or microcode, the program code or code segments to perform the necessary tasks may be stored in a machine readable medium. A processor(s) may direct the performance the at least some portion of any necessary tasks.

In one embodiment, a system for masking a portion of an envelope near the envelope's perimeter is provided. The envelope may be characterized by two lengthwise edges and two widthwise edges. In some embodiments, the system may be configured to mask an area starting at about ⅛ inches (about 3 millimeters) from one edge of the envelope. In some embodiments, the system may be configured to mask an area having a length of about 5¾ inches (about 146 millimeters), and a width of about ⅝ inches (about 16 millimeters). The system may include a supply mechanism configured to support an envelope, and provide the envelope to a first position. The supply mechanism may also be configured to support the envelope by supporting one of the lengthwise edge of the envelope. In some embodiments, the supply mechanism may be a conveyor mechanism.

The system may also include a transport mechanism configured to move the envelope from the first position to a second position. The transport mechanism may also be configured to move the envelope from the first position to the second position by moving the envelope from the first position to the second position with one of the widthwise edge being a leading edge as the envelope is moved. In some embodiments, the transport mechanism may include multiple transport belts. For example, in one embodiment, the system may have a first transport belt, a second transport belt, and a third transport belt. The envelope may move sequentially through these three belts as it moves from the first position to the second position. In some embodiments, a transport belt may define a void through the belt, and the system may further include a vacuum configured to pull air through the void and possibly encourage the envelope to contract and engage the transport belt.

The system may further include a masking apparatus configured to adhere a masking element to a portion of the envelope near the envelope's perimeter. In some embodiments, the masking apparatus may further be configured to adhere the masking element to the portion of the envelope near the envelope's perimeter while the envelope is between the first position and the second position. In an embodiment with multiple transport belts, the masking apparatus may be configured to adhere the masking element to the portion of the envelope near the envelope's perimeter while the envelope is between any two of the transport belts.

In some embodiments, the masking apparatus may include a supply of masking elements and a delivery mechanism. The delivery mechanism may be configured to deliver the masking element from the supply of masking elements to the envelope. The delivery mechanism may include a first portion and a second portion. The first portion may be coupled with a first surface at a first elevation, and the second portion may be coupled with a second surface at a second elevation. The second elevation may be higher than the first elevation, and the masking element may be adhered to the portion of the envelope near the envelope's perimeter by the second portion of the delivery mechanism.

In some embodiments, the supply of masking elements may include a length of material having a backing and a plurality of self-adhesive stickers. The masking apparatus in these or other embodiments may further include a take-up location to receive at least a portion of the backing after at least one of the self-adhesive stickers is adhered to the portion of the envelope near the envelope's perimeter.

In some embodiments, the masking apparatus may include a sensor which determines when the supply of masking elements has been moved a distance of about halfway between a first masking element to about halfway between a second masking element. The sensor may be an optical sensor configured to detect the difference between backing material with a sticker adhered to it and backing material without a sticker adhered to it. These, or other embodiments, may also include a movement device, controlled at least in part by the sensor, to move the supply of masking elements. When the supply of masking elements is moved, a single self adhesive sticker may be adhered to the portion of the envelope near the envelope's perimeter.

In some embodiments, the system may also include a receiving mechanism configured to receive the envelope from the second position and support the envelope. The receiving mechanism may possibly be a conveyor mechanism. In these or other embodiments, the system may be configured to mask about 130 envelopes per minute.

In another embodiment, a system for masking a portion of an envelope near the envelope's perimeter is provided. The system may include a means for providing an envelope to a first position. In some embodiments, the means for providing the envelope to the first position may include a conveyor mechanism.

The system may also include a means for moving the envelope from the first position to a second position. In some embodiments, the means for moving the envelope from the first position to the second position may include a transport mechanism. In some embodiments, the system may further include a means for encouraging the envelope to engage the means for moving the envelope from the first position to the second position.

The system may further include a means for adhering a masking element to a portion of the envelope near the envelope's perimeter. In some embodiments, the means for adhering a masking element to the portion of the envelope near the envelope's perimeter may include a means for supplying a masking element and a means for applying the masking element to the portion of the envelope near the envelope's perimeter. The means for supplying the masking element may be coupled with a first surface at a first elevation, and the means for applying the masking element to the portion of the envelope near the envelope's perimeter may be coupled with a second surface at a second elevation, and wherein the second elevation may be at a different height than the first elevation.

In some embodiments, the system may include a supply of masking elements a means for sensing when the supply of masking elements has been moved a distance of about halfway between a first masking element to about halfway between a second masking element, and a means for moving the supply of masking elements. The supply of masking elements may include a length of material having a backing and a plurality of self-adhesive stickers. The means for moving the supply of masking elements may be controlled at least in part by the means for sensing when the supply of masking elements has been moved a distance of about halfway between a first masking element to about halfway between a second masking element.

In some embodiments, the system may further include a means for receiving the envelope from the second position. In some embodiments, the means for receiving the envelope from the second position may include a conveyor mechanism.

In another embodiment, a method for masking a portion of an envelope near the envelope's perimeter is provided. The method may include providing an envelope and moving the envelope between a first position and a second position. The method may further include adhering a masking element to a portion of the envelope near the envelope's perimeter. In some embodiments, the masking element may be adhered to the envelope between the first position and the second position. In some embodiments, the method may further include receiving the envelope after the masking element has been adhered to the portion of the envelope near the envelope's perimeter.

In some embodiments, the method may further include providing a supply of masking elements. The supply of masking elements may include a length of material comprising a backing and a plurality of self-adhesive stickers. The method may further include sensing a distance the supply of masking elements is moved, and moving the supply of masking elements based at least on the sensed distance. When the supply of masking element is moved, at least one self-adhesive sticker may be adhered to the portion of the envelope near the envelope's perimeter.

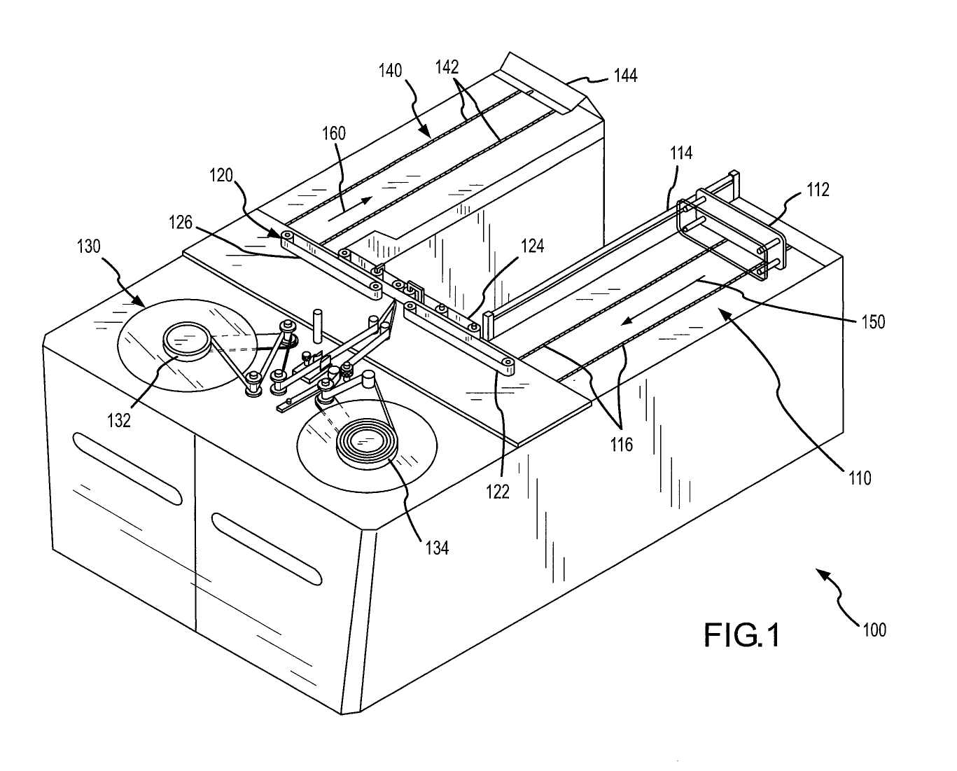

Turning now to FIG. 1, an axonometric drawing of a system 100 for masking a portion of an envelope near the envelope's perimeter is shown. System 100 includes a supply mechanism 110, a transport mechanism 120, a masking apparatus 130, and a receiving mechanism 140. Supply mechanism may include a support element 112, guided on a guide rod 114, and two tracks 116. A supply of envelopes to be masked may be supported on one of their lengthwise edges and moved by supply mechanism 110 in the direction of directional arrow 150.

As the supply of envelopes is moved toward transport mechanism 120, the foremost envelope will be collected by a first transport belt 122 of transport mechanism 120 and moved via a second transport belt 124 and a third transport belt 126. In this embodiment, masking apparatus 130 may adhere a masking element to the envelope as it moves through transport mechanism 120 by removing masking element from a supply of masking elements 132, adhering the masking element to the envelope, and collecting the used backing material 134.

After the envelope has been masked, it may be collected by receiving mechanism 140. Receiving mechanism may include two tracks 142 and an envelope stop 144 to keep collected envelopes from falling off the edge of the system 100. Receiving mechanism 140 may collect the envelopes received from masking apparatus and move them in the direction of directional arrow 160.

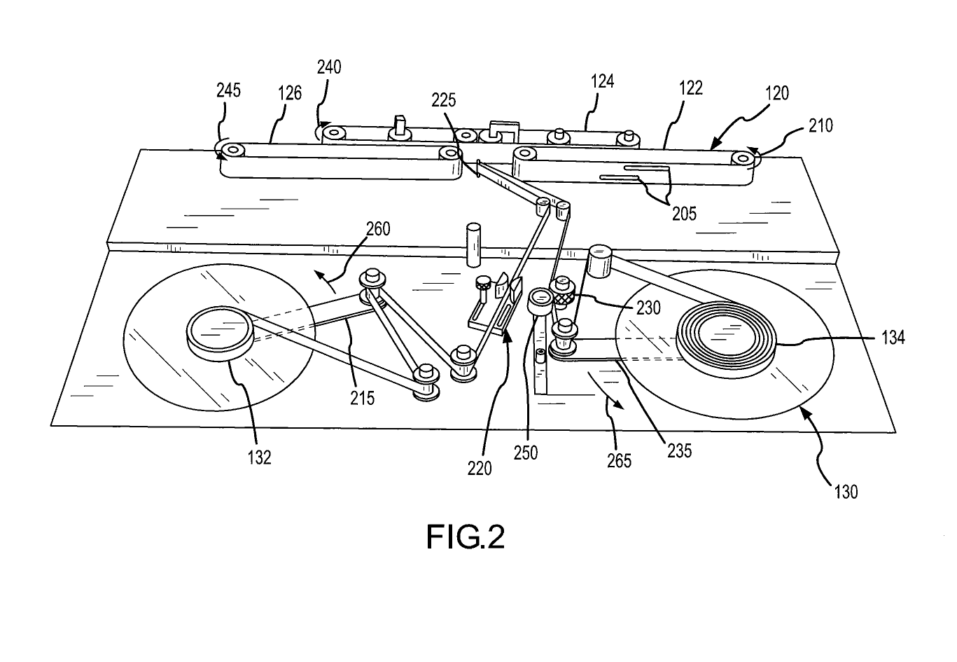

FIG. 2 shows a closer perspective view of transport mechanism 120 and masking apparatus 130 of the system 100 shown in FIG. 1. An envelope may be received by transport mechanism 120 at first transport belt 122. First transport belt 122 may have at least one void 205 through the belt's surface. A vacuum (not shown), may be situated inside the loop of first transport belt 122, and may move air from the outside of the belt to the inside of the belt through voids 205, thereby encouraging an envelope provided by the supply mechanism 110 to engage first transport belt 122.

Masking apparatus 130 may include supply of masking elements 132, a supply take-up arm 215, a sensor 220, an application pin 225, a drive wheel 230, a used backing take-up arm 235, and used backing material 134. Supply of masking elements 132 may include a lengthwise strip of backing with a plurality self adhesive stickers along the length of the backing. In other embodiments, masking elements may not be self adhesive, and a separate adhesive, possibly a liquid may be applied to either the envelope or the masking element to adhere it to the envelope. In some embodiments, drive wheel 230 may pull the masking elements through masking apparatus 130. Masking elements will be rotated off of supply of masking elements 132, around the pulley on the end of supply take-up arm 215, through sensor 220, and around application pin 225. As the masking elements are pulled around application pin 225, the tight turn of the masking elements about application pin 225 may cause an individual self adhesive sticker to be adhered to the envelope being moved by first transport belt 122, second transport belt 124, and third transport belt 126 which rotate in the direction indicated by directional arrows 210, 240, 245.

The used backing material may then be pulled around the pulley on the end of used backing take-up arm 235 and coiled with the remainder of used backing material 134. A pressure pulley 250 may be biased, possibly by a spring, toward drive wheel 230 to encourage the masking element backing to be engaged by drive wheel 230, which, as shown in this example, may be knurled to provide additional friction and grip on the adhesive backing.

Additionally, supply take-up arm 215 and used backing take-up arm 235 may be biased, possibly by springs, in the direction indicated by directional arrows 260, 265. Biased in these directions, sensors that detect the position of the arms may control motors which cause rotation of masking element supply 132 and used backing material 134. For example, a motor which may cause clockwise rotation of masking element supply 132 may only activate when supply take-up arm 215 is at a more clockwise position than shown in FIG. 2. As masking elements are rotated off of masking element supply 132, the biased supply take-up arm may rotate counterclockwise, taking up the slack of the masking elements. As masking elements are pulled through masking apparatus 130, supply take-up arm will rotate clockwise until the process is repeated, resupplying supply take-up arm 215 with additional slack. The use of supply take-up arm 215 may be advantageous over systems that time the activation and/or speed of the motor rotating the masking supply elements 132 to the speed of drive wheel 230. Used backing take-up arm 235 may operate in a similar fashion, collecting used backing by being biased in the direction indicated by directional arrow 265. A motor may then rotate used backing 134 in a clockwise direction, thereby collecting the used backing from the used backing take-up arm 235, thereby similarly removing the need to time the activation and/or speed of the rotation of the used backing 134.

Sensor 220 may detect spaces between self adhesive stickers on the backing and thereby control any of the systems or subsystems of the invention based on the movement of the masking elements. For example, drive wheel 230 may activate, and sensor 220 may detect the movement of a single self-adhesive sticker thereby deactivating drive wheel 230. In some embodiments, drive wheel 230 may be activated by a timer which coincides with the rotational period of first transport belt 122. For example, drive wheel 230 may be activated a certain amount of time after voids 205 are in a position where the vacuum encourages an envelope from supply mechanism 110 to engage first transport belt 122, thereby applying a masking element to the envelope at the proper position as the envelope proceeds through the transport mechanism 120.

Note that masking apparatus may include two portions at different elevations. The first portion may include the supply of masking elements 132, supply take-up arm 215, sensor 220, drive wheel 230, used backing take-up arm 235, and used backing 134. The second portion may include application pin 225. In some embodiments, the second portion may be higher than the first portion. This may allow for the masking element to be adhered to a portion of the envelope closer to an edge of the envelope by lowering the elevation of the masking elements relative to the bottom of the envelope as it passes by the application pin.

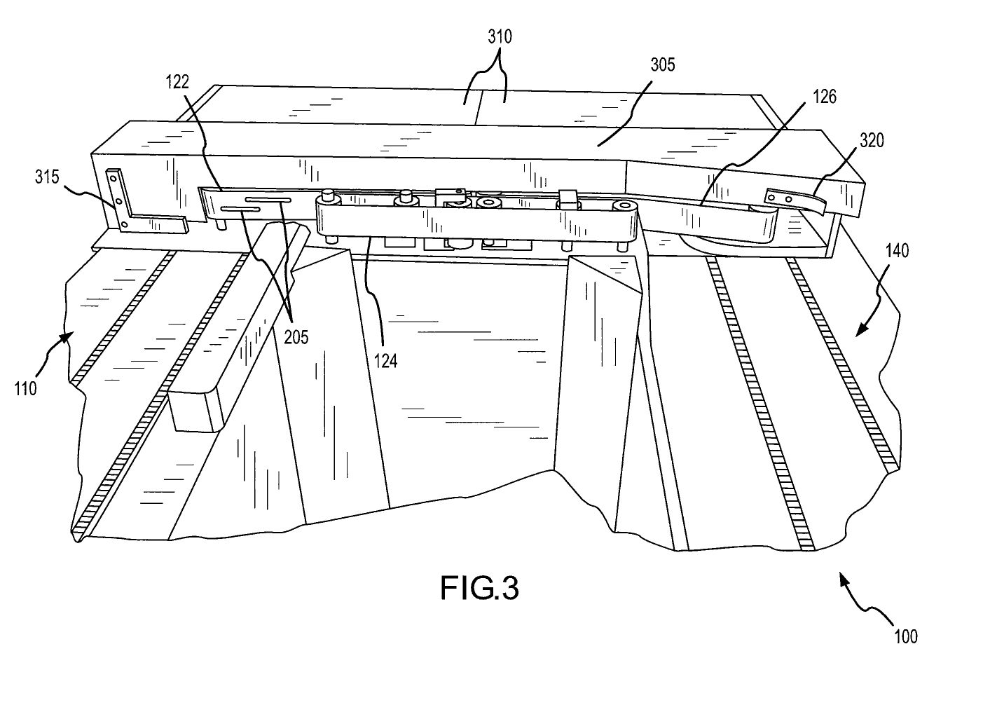

FIG. 3 shows a perspective view of the input and output areas of the system 100 shown in FIG. 1. In this view, safety covers 305, 310 are shown covering most of the workings of transport mechanism 120 and masking apparatus 130. An entry sensor arm 315 controls the activation of supply mechanism 110. In an initial position, a plurality of envelopes are located between support element 112 (shown on FIG. 1) and entry sensor arm 315. As envelopes leave supply mechanism 110 and enter transport mechanism 120, pressure may be relieved from entry sensor arm 315, and supply mechanism 110 may be activated to move the plurality of envelopes closer to transport mechanism 120. As pressure against entry sensor arm 315 is renewed by the plurality of envelopes, supply mechanism 110 may be deactivated.

After envelopes travel through transport mechanism 120 and have a masking element attached thereto by masking apparatus 130, the masked envelopes may exit to receiving mechanism 140. An exit guide arm 320 may cause the envelopes to fall toward envelope stop 144, and accumulate on receiving mechanism 140. A sensor in the surface of receiving mechanism 140, possibly optical or mechanical in operation, may activate the receiving mechanism intermittently, thereby moving the plurality of masked envelopes toward the envelope stop 144 to allow more envelopes to accumulate. In other embodiments, the receiving mechanism may continually be active during operation of the system. In these embodiments, the receiving mechanism may move at the rate necessary to allow the accumulation area to receive newly masked envelopes at a rate which corresponds to the speed at which envelopes can be masked by the remainder of the system.

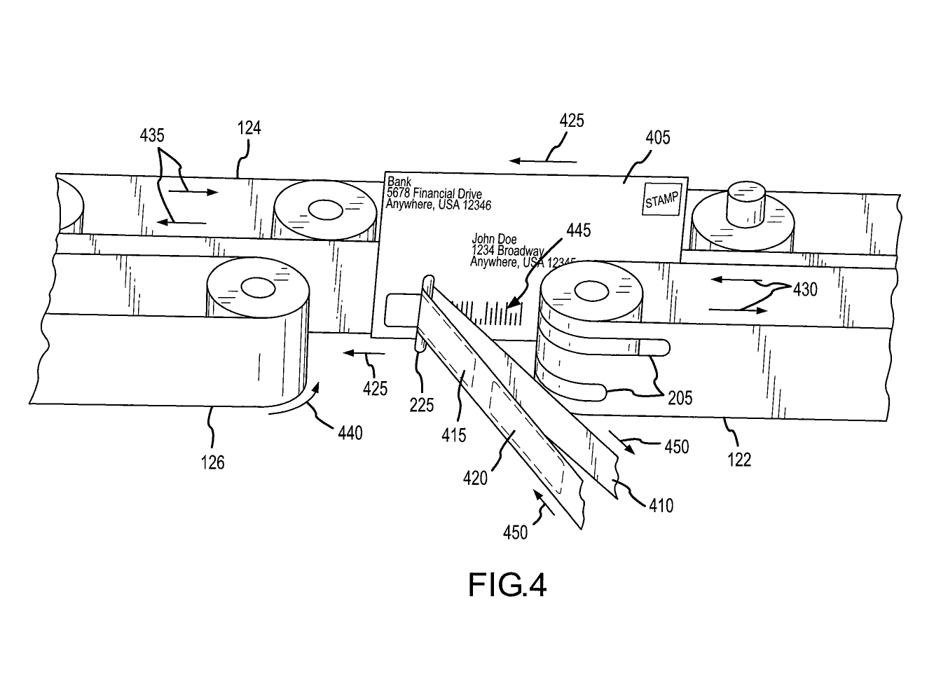

FIG. 4 shows a perspective view of a portion of the masking apparatus 130 showing an envelope 405 moving through transport mechanism 120. First transport belt 122 may be moving in the direction indicated by directional arrows 430; second transport belt 124 may be moving in the direction indicated by directional arrows 435; and third transport belt 126 may be moving in the direction indicated by directional arrows 440. The motion of transport belts 122, 124, 126 may cause envelope 405 to move in the direction of directional arrows 425 through the masking apparatus 130.

As envelope 405 moves through masking apparatus 130, backing material 410 may be moving around application pin 225 in the direction shown by directional arrows 450. This movement may cause self adhesive sticker 415 to disengage backing material 410, and adhere to envelope 405, possibly covering a bar code 445 that is desired to be masked (possibly because the bar code is in error, incomplete, or is otherwise not desired to remain on the envelope). A second self adhesive sticker 420 may then be in position to be applied to the next envelope that traverses the transport mechanism 120. After the envelopes are masked, they may possibly be reinserted into another machine so that a corrected bar code may be applied to the masked envelope. Other types of markings besides bar codes may also be masked by this or other embodiments of the invention, including, but not limited to, alphanumeric text and graphics.

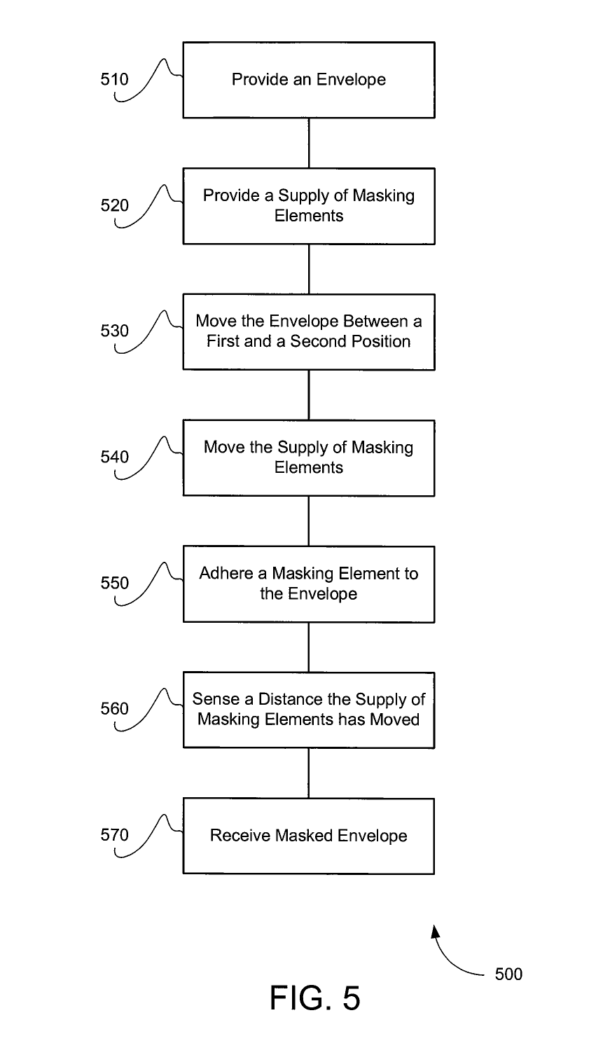

FIG. 5 is a block diagram of one method 500 of the invention for masking a portion of an envelope near the envelope's perimeter. At block 510, an envelope is provided. At block 520, a supply of masking elements is provided. At block 530, the envelope may be moved between a first position and a second position. At block 540, the supply of masking elements may be moved, possibly causing at least one masking element to be adhered to the envelope at block 550. As the masking element is adhered to the envelope, the method may sense the distance that the supply of masking elements is moves at block 560, and stop moving the supply of masking elements once adhesion has been completed. At block 570, the masked envelope may be received.

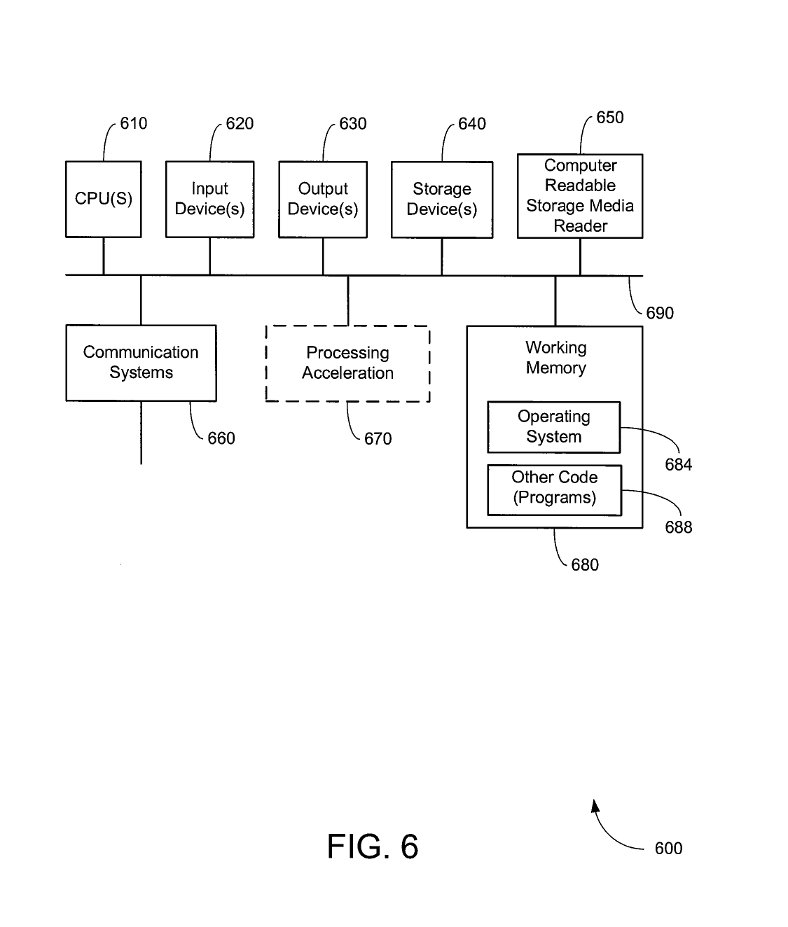

FIG. 6 is a block diagram illustrating an exemplary computer system 600 in which embodiments of the present invention may be implemented. This example illustrates a computer system 600 such as may be used, in whole, in part, or with various modifications, to provide or control the functions of the supply mechanism, the transport mechanism, the masking apparatus, the receiving mechanism, the vacuum, the delivery mechanism, the sensor, the movement device, the conveyor mechanisms, and/or other components of the invention such as those discussed above. For example, various functions of the sensor and the movement device may be controlled by the computer system 600, including, merely by way of example, activating and deactivating the movement device, possibly based upon input from the sensor.

The computer system 600 is shown comprising hardware elements that may be electrically coupled via a bus 690. The hardware elements may include one or more central processing units 610, one or more input devices 620 (e.g., a mouse, a keyboard, etc.), and one or more output devices 630 (e.g., a display device, a printer, etc.). The computer system 600 may also include one or more storage device 640. By way of example, storage device(s) 640 may be disk drives, optical storage devices, solid-state storage device such as a random access memory (“RAM”) and/or a read-only memory (“ROM”), which can be programmable, flash-updateable and/or the like.

The computer system 600 may additionally include a computer-readable storage media reader 650, a communications system 660 (e.g., a modem, a network card (wireless or wired), an infra-red communication device, Blutetooth™ device, cellular communication device, etc.), and working memory 680, which may include RAM and ROM devices as described above. In some embodiments, the computer system 600 may also include a processing acceleration unit 670, which can include a digital signal processor, a special-purpose processor and/or the like.

The computer-readable storage media reader 650 can further be connected to a computer-readable storage medium, together (and, optionally, in combination with storage device(s) 640) comprehensively representing remote, local, fixed, and/or removable storage devices plus storage media for temporarily and/or more permanently containing computer-readable information. The communications system 660 may permit data to be exchanged with a network, system, computer and/or other component described above.

The computer system 600 may also comprise software elements, shown as being currently located within a working memory 680, including an operating system 684 and/or other code 688. It should be appreciated that alternate embodiments of a computer system 600 may have numerous variations from that described above. For example, customized hardware might also be used and/or particular elements might be implemented in hardware, software (including portable software, such as applets), or both. Furthermore, connection to other computing devices such as network input/output and data acquisition devices may also occur.

Software of computer system 600 may include code 688 for implementing any or all of the function of the various elements of the architecture as described herein. For example, software, stored on and/or executed by a computer system such as system 600, can provide the functions of the supply mechanism, the transport mechanism, the masking apparatus, the receiving mechanism, the vacuum, the delivery mechanism, the sensor, the movement device, the conveyor mechanisms, and/or other components of the invention such as those discussed above. Methods implementable by software on some of these components have been discussed above in more detail.

The invention has bow been described in detail for the purposes of clarity and understanding. However, it will be appreciated that certain changes and modifications may be practiced within the scope of the appended claims.

What is claimed is:

1. A system for masking a portion of an envelope near the envelope's perimeter, wherein the system comprises:
a supply mechanism configured to:
support an envelope; and
provide the envelope to a first position;
a transport mechanism configured to move the envelope from the first position to a second position; and
a masking apparatus configured to adhere a masking element to a portion of the envelope near the envelope's perimeter.

2. The system for masking a portion of an envelope near the envelope's perimeter of claim 1, wherein the envelope is characterized by two lengthwise edges and two widthwise edges, and wherein the supply mechanism being configured to support the envelope comprises the supply mechanism being configured to support one of the lengthwise edge of the envelope.

3. The system for masking a portion of an envelope near the envelope's perimeter of claim 1, wherein the envelope is characterized by two lengthwise edges and two widthwise edges, and wherein the transport mechanism being configured to move the envelope from the first position to the second position comprises the transport mechanism being configured to move the envelope from the first position to the second position with one of the widthwise edge being a leading edge as the envelope is moved.

4. The system for masking a portion of an envelope near the envelope's perimeter of claim 1, wherein the system further comprises a receiving mechanism configured to:
receive the envelope from the second position; and
support the envelope.

5. The system for masking a portion of an envelope near the envelope's perimeter of claim 4, wherein the receiving mechanism comprises a conveyor mechanism.

6. The system for masking a portion of an envelope near the envelope's perimeter of claim 1, wherein the masking apparatus is further configured to adhere the masking element to the portion of the envelope near the envelope's perimeter while the envelope is between the first position and the second position.

7. The system for masking a portion of an envelope near the envelope's perimeter of claim 1, wherein the supply mechanism comprises a conveyor mechanism.

8. The system for masking a portion of an envelope near the envelope's perimeter of claim 1, wherein the transport mechanism comprises a first transport belt, and the first transport belt defines at least one void through the first transport belt, and wherein the system further comprises a vacuum configured to pull air through the at least one void and encourage the envelope to contact the first transport belt.

9. The system for masking a portion of an envelope near the envelope's perimeter of claim 8, wherein the transport mechanism further comprises a second transport belt and a third transport belt, wherein the envelope contacts the first transport belt, then the second transport belt, then the third transport belt as it moves between the first position and the second position.

10. The system for masking a portion of an envelope near the envelope's perimeter of claim 9, wherein masking apparatus is configured to adhere the masking element to the portion of the envelope near the envelope's perimeter while the envelope is between the first transport belt and the third transport belt.

11. The system for masking a portion of an envelope near the envelope's perimeter of claim 1, wherein the masking apparatus comprises:
a supply of masking elements; and
a delivery mechanism to deliver the masking element from the supply of masking elements to the envelope, wherein the delivery mechanism comprises:
a first portion coupled with a first surface at a first elevation; and
a second portion coupled with a second surface at a second elevation, wherein the second elevation is higher than the first elevation, and wherein the masking element is adhered to the portion of the envelope near the envelope's perimeter by the second portion of the delivery mechanism.

12. The system for masking a portion of an envelope near the envelope's perimeter of claim 11, wherein the supply of masking elements comprises a length of material comprising a backing and a plurality of self-adhesive stickers, and wherein the masking apparatus further comprises a take-up location to receive at least a portion of the backing after at least one of the self-adhesive stickers is adhered to the portion of the envelope near the envelope's perimeter.

13. The system for masking a portion of an envelope near the envelope's perimeter of claim 1, wherein the masking apparatus comprises:
a supply of masking elements, wherein the supply of masking elements comprise a length of material comprising a backing and a plurality of self-adhesive stickers;
a sensor which determines when the supply of masking elements has been moved a distance of about halfway between a first masking element to about halfway between a second masking element; and
a movement device, controlled at least in part by the sensor, to move the supply of masking elements, wherein when the supply of masking elements is moved, a single self adhesive sticker is adhered to the portion of the envelope near the envelope's perimeter.

14. A system for masking a portion of an envelope near the envelope's perimeter, wherein the system comprises:
a means for providing an envelope to a first position;
a means for moving the envelope from the first position to a second position; and
a means for adhering a masking element to a portion of the envelope near the envelope's perimeter.

15. The system for masking a portion of an envelope near the envelope's perimeter of claim 14, wherein the system further comprises a means for receiving the envelope from the second position.

16. The system for masking a portion of an envelope near the envelope's perimeter of claim 15, wherein the means for receiving the envelope from the second position comprises a conveyor mechanism.

17. The system for masking a portion of an envelope near the envelope's perimeter of claim 14, wherein the means for providing the envelope to the first position comprises a conveyor mechanism.

18. The system for masking a portion of an envelope near the envelope's perimeter of claim 14, wherein the means for moving the envelope from the first position to the second position comprises a transport mechanism.

19. The system for masking a portion of an envelope near the envelope's perimeter of claim 14, wherein the system further comprises a means for encouraging the envelope to engage the means for moving the envelope from the first position to the second position.

20. The system for masking a portion of an envelope near the envelope's perimeter of claim 14, wherein the means for adhering a masking element to the portion of the envelope near the envelope's perimeter comprises:
a means for supplying a masking element, wherein the means for supplying the masking element is coupled with a first surface at a first elevation; and
a means for applying the masking element to the portion of the envelope near the envelope's perimeter, wherein the means for applying the masking element to the portion of the envelope near the envelope's perimeter is coupled with a second surface at a second elevation, and wherein the second elevation is higher than the first elevation.

21. The system for masking a portion of an envelope near the envelope's perimeter of claim 14, wherein the system further comprises:
a supply of masking elements, wherein the supply of masking elements comprise a length of material comprising a backing and a plurality of self-adhesive stickers;
a means for sensing when the supply of masking elements has been moved a distance of about halfway between a first masking element to about halfway between a second masking element; and
a means for moving the supply of masking elements, wherein the means for moving the supply of masking elements is controlled at least in part by the means for sensing when the supply of masking elements has been moved a distance of about halfway between a first masking element to about halfway between a second masking element.

22. A method for masking a portion of an envelope near the envelope's perimeter, wherein the system comprises:
providing an envelope;
moving the envelope between a first position and a second position; and
adhering a masking element to a portion of the envelope near the envelope's perimeter.

23. The method for masking a portion of an envelope near the envelope's perimeter of claim 22, wherein the masking element is adhered to the envelope between the first position and the second position.

24. The method for masking a portion of an envelope near the envelope's perimeter of claim 22, wherein the method further comprises receiving the envelope after the masking element has been adhered to the portion of the envelope near the envelope's perimeter.

25. The method for masking a portion of an envelope near the envelope's perimeter of claim 22, wherein the method further comprises:
providing a supply of masking elements, wherein the supply of masking elements comprise a length of material comprising a backing and a plurality of self-adhesive stickers;
sensing a distance the supply of masking elements is moved; and
moving the supply of masking elements based at least on the sensed distance, wherein when the supply of masking element is moved, at least one self-adhesive sticker is adhered to the portion of the envelope near the envelope's perimeter.
